(19) United States
(12) Patent Application Publication
(10) Pub. No.: US 2026/0367125 A1
(43) Pub. Date: Nov. 19, 2026

(54) TEST AND/OR MEASUREMENT SYSTEM AND SIGNAL PROCESSING METHOD

(71) Applicant: Rohde & Schwarz GmbH & Co. KG, Muenchen (DE)

(72) Inventors: Thomas MAIER, Muenchen (DE); Hans SCHLECHT, Muenchen (DE); Michael WOEHRLE, Muenchen (DE)

(21) Appl. No.: 19/208,900

(22) Filed: May 15, 2025

(51) Int. Cl. G01R 29/08

(52) U.S. Cl. CPC G01R 29/0871

(57) ABSTRACT

A system for analyzing at least a portion of a broadband signal includes at least one signal splitting circuit, a switching matrix circuit, and a signal processing circuit. The signal splitting circuit includes a signal input being configured to receive a radio frequency (RF) input signal. The signal splitting circuit includes n signal outputs, wherein n is an integer greater than or equal to 2. The signal splitting circuit is configured to split the RF input signal into n RF output signals, wherein the n RF output signals correspond to different sub-bands of the RF input signal, and wherein the signal splitting circuit is configured to forward the n RF output signals to the n signal outputs. The switching matrix circuit is connected to each of the n signal outputs. The switching matrix circuit is configured to selectively output m RF output signals of the n RF output signals.

### FIELD OF THE DISCLOSURE

Embodiments of the present disclosure generally relate to a test and/or measurement system for analyzing at least a portion of a broadband signal. Embodiments of the present disclosure further relate to a signal processing method for analyzing at least a portion of a broadband signal.

### BACKGROUND

Measurements of broadband pulse signals, such as electromagnetic interference measurements, require a high dynamic range of the receiver due to potentially big differences between peak portions of the pulse signal and other portions of the pulse signal to be measured.

The achievable radio frequency (RF) bandwidth is limited by the dynamic range of the components of the measurement instrument used, wherein increased dynamic range is, in general, associated with higher costs.

In the state of the art, it is known to reduce the required bandwidth at the critical components of the receiver with preselection filters. Then, the measurement is done sequentially for every filter path and measurement frequency. However, this increases the measurement time necessary for performing the measurements considerably.

Thus, there is a need for a test and/or measurement system as well as for a signal processing method that allow for optimized processing and analysis of broadband signals.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide a test and/or measurement system for analyzing at least a portion of a broadband signal. In an embodiment, the test and/or measurement system comprises at least one signal splitting circuit, a switching matrix circuit, and a signal processing circuit. The at least one signal splitting circuit comprises a signal input being configured to receive a radio frequency (RF) input signal. The at least one signal splitting circuit comprises n signal outputs, wherein n is an integer greater than or equal to 2. The at least one signal splitting circuit is configured to split the RF input signal into n RF output signals, wherein the n RF output signals correspond to different sub-bands of the RF input signal, and wherein the at least one signal splitting circuit is configured to forward the n RF output signals to the n signal outputs. The switching matrix circuit is connected to each of the n signal outputs. The switching matrix circuit is configured to selectively output m RF output signals of the n RF output signals, wherein m is an integer smaller than n, and wherein the signal processing circuit is configured to process the m RF output signals in parallel.

Processing the m RF output signals in parallel is understood to denote arbitrary signal shaping operations, conversion into digital signals, and/or analysis of the m RF output signals or of signals derived from the m RF output signals.

Further, it is to be understood that split signals are always applied to all of the respectively connected signal paths simultaneously. Accordingly, a switch selectively forwarding the RF signal only to a certain signal path does not “split” the RF signal.

The RF input signal may be a broadband signal, i.e. a useful signal comprised in the RF input signal may have a bandwidth being larger than a predefined threshold. For example, the RF input signal may have a bandwidth of at least 500 MHz, of at least 1 GHz, of at least two GHz or even larger.

The test and/or measurement system according to the present disclosure is based on the idea to split the RF input signal into the n RF output signals, wherein each RF output signal comprises a different frequency sub-band of the original frequency band of the RF input signal.

In an embodiment, the switching matrix circuit selects m of the n RF output signals which are then processed in parallel by the signal processing circuit. Accordingly, compared to a serial processing of the individual sub-bands, the processing time necessary for processing the RF input signal is reduced by a factor of m.

In an embodiment, the number m of signals processed simultaneously may be adaptable. Therein, the number m of signals processed simultaneously can be adapted by appropriately controlling the switching matrix circuit, such that RF input signals having different bandwidths can be processed optimally.

According to an aspect of the present disclosure, the at least one signal splitting circuit, for example, comprises at least one filter circuit for each of the n RF output signals. In an embodiment, the filter circuits are configured to confine the n RF output signals to the respective sub-band. In other words, only a predetermined set of frequencies, namely the respective sub-band, passes each filter, while the remaining frequencies of the RF input signal are filtered out.

In an embodiment, the sub-bands passing the filter circuits may be complementary, such that the different sub-bands together cover the original frequency band of the RF input signal.

In an example embodiment, the signal processing circuit comprises at least two analog-to-digital converters, ADCs, wherein the at least two ADCs are arranged in parallel. Accordingly, the at least two ADCs simultaneously digitize the m RF output signals simultaneously, such that the time necessary for digitizing the RF input signal is reduced considerably.

In an embodiment, the signal processing circuit may comprise an arbitrary number of ADCs, namely up to n-1 ADCs being arranged in parallel.

Accordingly, it is not necessary to provide an ADC for each of the n RF output signals, which reduces the manufacturing costs of the test and/or measurement system.

In an embodiment, the signal processing circuit may comprise m ADCs being arranged in parallel, such that all m selected RF output signals can be digitized by different ADCs in parallel.

In an embodiment, the at least two ADCs are configured to digitize the RF outputs signals or processed versions of the RF output signals.

According to another aspect of the present disclosure, the at least two different ADCs are configured, for example, to digitize different sub-bands of the RF input signal simultaneously. Accordingly, the time necessary for digitizing the different sub-bands is reduced, thereby further reducing the processing time necessary for processing the RF input signal.

In an embodiment, the different sub-bands digitized by the at least two ADCs simultaneously may be adjacent, for example immediately adjacent to each other in frequency domain.

In another embodiment, the at least two ADCs are each configured to digitally down-convert a frequency of the respective RF output signal and/or to decimate the respective RF output signal. Accordingly, the at least two ADCs may be configured to reduce frequencies of the digitized RF output signals and/or reduce sample rates of the digitized output signals, which reduces computational requirements on components downstream of the at least two ADCs.

For example, the at least two ADCs may each be configured to down-convert a frequency of the respective RF output signal into the baseband.

Another aspect of the present disclosure provides, for example, that the at least one signal splitting circuit, the switching matrix circuit, and the signal processing circuit are free of frequency conversion mixers upstream of the at least two ADCs. In other words, no frequency down-conversion may take place upstream of the at least two ADCs. Accordingly, the at least two ADCs may operate on the original frequency band, or more precisely on specific sub-bands of the original frequency band of the original RF input signal.

According to a further aspect of the present disclosure, the signal processing circuit, for example, comprises a digital signal processing circuit being arranged downstream of the at least two ADCs. In an embodiment, the digital signal processing is configured to analyze signals digitized by the at least two ADCs in parallel. As the digitized signals are analyzed simultaneously, the time necessary for analyzing the RF input signal is further reduced.

In an embodiment, the digital signal processing circuit may comprise a plurality of fast Fourier transform (FFT) circuits. The plurality of FFT circuits are connected to the at least two ADCs, wherein the plurality of FFT circuits is configured to apply an FFT to one of the signals digitized by the at least two ADCs, respectively, and wherein frequency bins of the FFT circuits are distributed over the respective sub-bands associated with the signals digitized by the at least two ADCs. Accordingly, the plurality of FFT circuits transform the signals digitized by the at least two ADCs into frequency domain for further processing downstream of the plurality of FFT circuits. The frequency bins of the FFT circuits being distributed over the respective sub-bands ensures that each sub-band can be further processed and/or analyzed optimally.

According to an aspect of the present disclosure, the at least one signal splitting circuit, for example, is configured to level the n RF output signals individually. In other words, the at least one signal splitting circuit may amplify and/or attenuate the RF output signals being associated with different sub-bands individually. Thus, it is ensured that each sub-band can be processed optimally by ensuring that the signal levels are within a predefined range.

In an embodiment, each sub-band can be amplified or attenuated individually such that each of the resulting amplified and/or attenuated signals is within the dynamic ranges of the components downstream of the at least one signal splitting circuit, for example within the dynamic ranges of the at least two ADCs.

According to another aspect of the present disclosure, the at least one signal splitting circuit, for example, comprises at least one amplifier for each of the n RF output signals. Thus, the RF output signals can be amplified individually to ensure that each of the RF output signals has sufficient signal level for processing and/or analysis downstream of the at least one signal splitting circuit.

In an example embodiment, the at least one signal splitting circuit comprises at least one attenuator for each of the n RF output signals. Thus, the RF output signals can be attenuated individually to ensure that none of the RF output signals exceeds the dynamic ranges of components downstream of the at least one signal splitting circuit.

In another embodiment, the at least one splitting circuit comprises a first splitter stage, wherein the first splitter stage is configured to split the RF input signal into a first set of intermediate RF signals, wherein the first set of intermediate RF signals correspond to different sub-bands of the RF input signal.

In an embodiment, the first splitter stage may be the only splitter stage. In this case, the first set of intermediate RF signals has n intermediate RF signals corresponding to the n RF output signals. Alternatively, a plurality of consecutive splitter stages may be provided. In this case, the first set of intermediate RF signals comprises j₁ intermediate RF signals, wherein j₁ is an integer smaller than n.

In an embodiment, j₁ may be a proper divisor of n.

In an embodiment, the first splitter stage may comprise at least one of an amplifier, an attenuator, or a filter circuit for each of the intermediate RF signals.

Accordingly, the first splitter stage may be configured to level each of the intermediate RF signals individually by amplifying and/or attenuating the intermediate RF signals by the amplifiers and attenuators, respectively.

Alternatively or additionally, the filter circuits may be configured to confine the intermediate RF signals to the respective sub-band.

In another embodiment, the at least one splitting circuit comprises a second splitter stage that is arranged downstream of the first splitter stage, wherein the second splitter stage is configured to split the first set of intermediate RF signals into a second set of intermediate RF signals.

In an embodiment, each intermediate RF signal of the first set of intermediate RF signals may be split into at least two intermediate RF signals of the second set of intermediate RF signals.

In general, the second set of intermediate RF signals may cover the same overall frequency band as the first set of intermediate signals, wherein each intermediate RF signal of the second set of intermediate RF signals covers a sub-set of frequencies of the sub-band covered by the respective intermediate RF signal of the first set of intermediate RF signals.

In an embodiment, the second set of intermediate RF signals may correspond to the n RF output signals, i.e. the second set of intermediate RF signals may comprise n intermediate RF signals.

Alternatively, at least one further splitter stage may be provided downstream of the second splitter stage. In this case, the second set of intermediate RF signals comprises j₂ intermediate RF signals, wherein j₂ is an integer smaller than n.

In an embodiment, j₂ may be a proper divisor of n.

In an embodiment, the, j₁ may be a proper divisor of j₂.

According to an aspect of the present disclosure, the second splitter stage comprises, for example, at least one of an amplifier, an attenuator, or a filter circuit for each of the intermediate RF signals.

Accordingly, the second splitter stage may be configured to level each of the intermediate RF signals individually by amplifying and/or attenuating the intermediate RF signals by the amplifiers and attenuators, respectively.

Alternatively or additionally, the filter circuits may be configured to confine the intermediate RF signals to the respective sub-band.

In an embodiment, the test and/or measurement system may further comprise a switching circuit. The at least one splitting circuit comprises a first splitting circuit and a second splitting circuit, wherein the first splitting circuit and the second splitting circuit are each connected to the switching circuit, wherein the switching circuit is configured to receive the RF input signal, and wherein the switching circuit is configured to selectively forward the RF input signal to either the first splitting circuit or the second splitting circuit. Accordingly, the RF input signal Is either processed by the first splitting circuit or by the second splitting circuit.

Therein, the first splitting circuit and the second splitting circuit may be configured to process different frequency bands, as will be described in more detail below.

In an embodiment, the first splitting circuit may be configured according to any one of the embodiments described above with respect to the “at least one splitting circuit”.

Likewise, the second splitting circuit may be configured according to any one of the embodiments described above with respect to the “at least one splitting circuit”.

In an embodiment, the first splitting circuit and the second splitting circuit may each be configured to split the RF input signal into n RF output signals.

In another example embodiment, the switching matrix circuit is connected to both the first splitting circuit and the second splitting circuit. As only one of the first splitting circuit and the second splitting circuit is active at a time, the switching matrix circuit always receives n RF output signals, namely either from the first splitting circuit or from the second splitting circuit.

An aspect of the present disclosure provides that the first splitting circuit and the second splitting circuit are configured, for example, to process different frequency portions of the RF input signal. Thus, an even larger bandwidth of the RF input signal can be covered by the first splitting circuit and the second splitting circuit.

In an embodiment, the different frequency portions may be adjacent, for example immediately adjacent to each other in frequency space.

In an embodiment, the different frequency portions may be complementary, such that the different frequency portions together cover the original frequency band of the RF input signal.

According to a further aspect of the present disclosure, the different sub-bands, for example, are overlap-free. In other words, each frequency of the original RF input signal is exclusively contained in only one of the RF output signals. However, it is also conceivable that adjacent sub-bands may have a defined overlap in frequency space.

Embodiments of the present disclosure further provide a signal processing method for analyzing at least a portion of a broadband signal. In an embodiment, the signal processing method comprises receiving, by at least one signal splitting circuit, a radio frequency (RF) input signal; splitting, by the at least one splitting circuit, the RF input signal into n RF output signals, wherein the n RF output signals correspond to different sub-bands of the RF input signal, and wherein n is an integer greater than or equal to 2; outputting, by the splitting circuit, the n RF output signals via n signal outputs; selectively outputting, by a switching matrix circuit, m RF output signals of the n RF output signals, wherein m is an integer smaller than n; and processing, by a signal processing circuit, the m RF output signals in parallel.

In an embodiment, the test and/or measurement system according to any one of the embodiments described above may be configured to perform any one of (or all of) the signal processing methods according to the present disclosure.

Regarding the advantages and further properties of the signal processing method, reference is made to the explanations given above with respect to the test and/or measurement system, which also hold for the signal processing method and vice versa.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a test and/or measurement system according to an embodiment of the present disclosure;

FIG. 2 schematically shows a first embodiment of a measurement circuit of the test and/or measurement system of FIG. 1;

FIG. 3 schematically shows a second embodiment of a measurement circuit of the test and/or measurement system of FIG. 1;

FIG. 4 schematically shows a third embodiment of a measurement circuit of the test and/or measurement system of FIG. 1;

FIG. 5 schematically shows a fourth embodiment of a measurement circuit of the test and/or measurement system of FIG. 1; and

FIG. 6 shows an example of a flow chart of a signal processing method according to an embodiment of the present disclosure.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

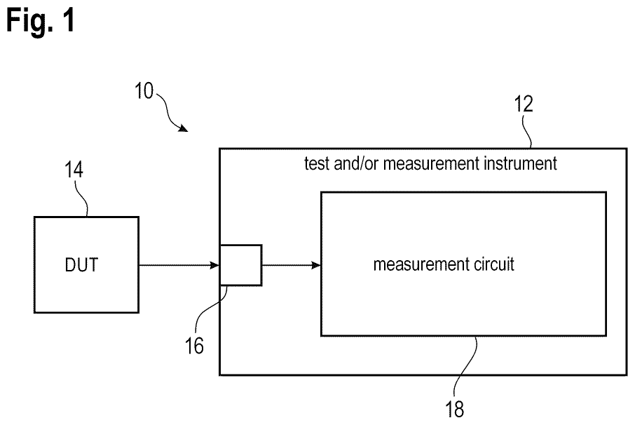

FIG. 1 schematically shows a test and/or measurement system 10 comprising a test and/or measurement instrument 12 and a device under test 14. The test and/or measurement instrument 12 may, for example, be a signal analyzer, a spectrum analyzer, a vector network analyzer, an oscilloscope, for example a digital oscilloscope, or any other suitable type of test and/or measurement instrument.

The device under test 14 is an electronic device being configured to generate, process and/or output a broadband radio frequency (RF) signal. For example, the device under test 14 may be a mobile communication device such as a smartphone or a radio, a base station, a mixer, an amplifier, a filter, or any other type of electronic device being configured to generate, process and/or output a broadband RF signal.

In general, the test and/or measurement instrument 12 is configured to perform measurements on the RF signal output by the device under test 14. The test and/or measurement instrument 12 comprises at least one signal input 16 that is connected to the device under test 14 so as to receive the RF signal.

It is noted that, while the device under test 14 is shown to be connected to the test and/or measurement instrument 12 directly in FIG. 1, the device under test 14 may alternatively be tested over the air. In this case, one or several RF antennas may receive the RF signal transmitted by the device under test 14, and may forward the received RF signal to the test and/or measurement instrument 12.

The test and/or measurement instrument 12 further comprises a measurement circuit 18 that is arranged downstream of the at least one signal input 16. The measurement circuit 18 is configured to receive and process the RF signal received by the at least one signal input 16, as will be described in more detail hereinafter. It is noted that further signal-processing components may be provided between the at least one signal input 16 and the measurement circuit 18.

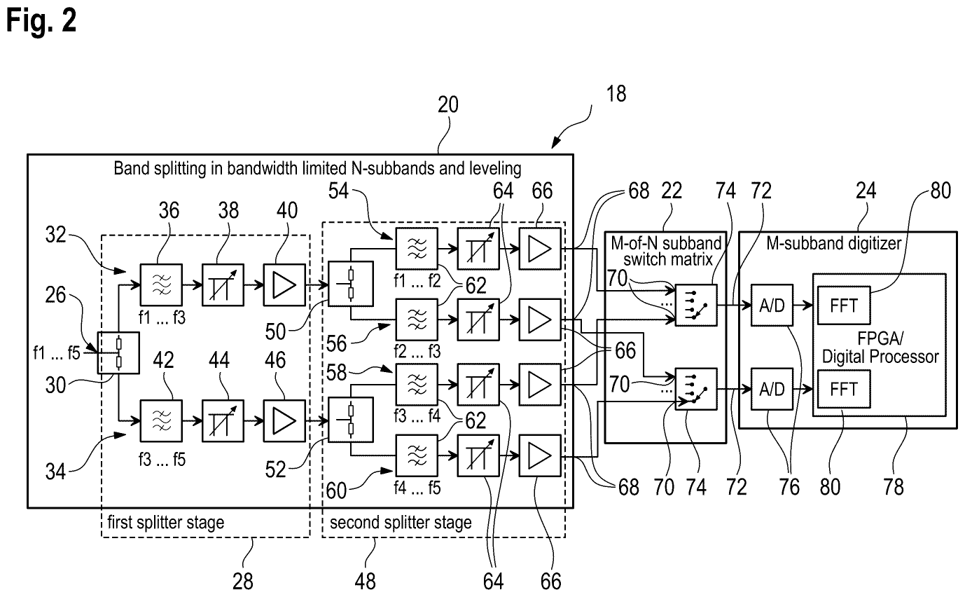

FIG. 2 shows an example of the measurement circuit 18 in more detail. The measurement circuit 18 comprises a signal splitting circuit 20, a switching matrix circuit 22, and a signal processing circuit 24.

The signal splitting circuit 20 comprises a signal input 26 being connected to the at least one signal input 16 of the test and/or measurement instrument 12. The signal input 26 is configured to receive an RF input signal that corresponds to the RF signal received by the signal input 16, i.e. the RF input signal is the RF signal or a processed version thereof.

In an embodiment, the RF input signal may be a broadband signal, wherein a useful signal of the RF input signal covers a frequency band spanning from a lower frequency f1 to an upper frequency f5. In an embodiment, the RF input signal may be a pulsed signal comprising a single pulse or a series of pulses. However, it is to be understood that the RF input signal may be any other type of broadband signal.

For example, the lower frequency f1 may be 15 MHz, 30 MHz, or 50 MHz. However, it is to be understood that the lower frequency f1 may be lower than 15 MHz, higher than 50 MHz, or may take any value between the exemplary frequencies given above.

According to a further example, the upper frequency f5 may be 500 MHz, 1 GHz, or 2 GHz. However, it is to be understood that the upper frequency f5 may be lower than 500 MHz, higher than 2 GHz, or may take any value between the exemplary frequencies given above.

In an embodiment, the signal splitting circuit 20 comprises a first splitter stage 28 that is connected to the signal input 26. In an embodiment, the first splitter stage 28 comprises a first splitter unit 30 being connected to the signal input 26. For example, the first splitter unit 30 may be a power splitter, a crossover unit, for example a diplexer, or any other suitable type of splitter unit.

In an embodiment, the first splitter stage 28 further comprises j₁ signal processing paths, wherein each of the signal processing paths is connected to the first splitter unit 30 and is arranged downstream of the first splitter unit 30. In general, j₁ is an integer greater than or equal to 2. In the example embodiment shown in FIG. 2, j₁ is equal to 2, i.e. the first splitter stage 28 comprises a first signal processing path 32 and a second signal processing path 34. Without restriction of generality, this example case of j₁=2 is described hereinafter.

In an embodiment, the first signal processing path 32 comprises a first filter circuit 36 that is connected, for example immediately connected, to the first splitter unit 30. The first filter circuit 36 may be a bandpass filter being configured to pass a specific frequency range. In the example shown in FIG. 2, the first filter circuit 36 is configured to pass frequencies between f1 and f3, wherein it holds f1<f3<f5. In an embodiment, f3 may be the average of f1 and f5, i.e. f3=(f1+f5)/2.

In an embodiment, the first signal processing path 32 further comprises a first attenuator 38 and a first amplifier 40 that are arranged downstream of the first filter circuit 36. In an embodiment, the second signal processing path 34 comprises a second filter circuit 42 that is connected, for example immediately connected, to the first splitter unit 30.

In an embodiment, the second filter circuit 42 may be a bandpass filter being configured to pass a specific frequency range. In the example shown in FIG. 2, the second filter circuit 42 is configured to pass frequencies between f3 and f5.

In an embodiment, the second signal processing path 34 further comprises a second attenuator 44 and a second amplifier 46 that are arranged downstream of the second filter circuit 42.

In an embodiment, the signal splitting circuit 20 further comprises a second splitter stage 48 that is arranged downstream of the first splitter stage 28. For instance, the second splitter stage 48 comprises a second splitter unit 50 that is connected to the first signal processing path 32, as well as a third splitter unit 52 that is connected to the second signal processing path 34. For example, the second splitter unit 50 may be a power splitter, a crossover unit, for example a diplexer, or any other suitable type of splitter unit. Likewise, the third splitter unit 52 may be a power splitter, a crossover unit, for example a diplexer, or any other suitable type of splitter unit.

In an embodiment, the second splitter stage 48 further comprises j₂ signal sub-paths, wherein half of the j₂ signal processing paths is connected to the second splitter unit 50 and the other half of the j₂ signal processing paths is connected to the third splitter unit 52.

In the example embodiment shown in FIG. 2, the second splitter unit 50 and the third splitter unit 52 are each connected to two signal sub-paths. Accordingly, the second splitter stage 48 comprises a first signal sub-path 54 and a second signal sub-path 56 that are connected to the second splitter unit 50.

In an embodiment, the second splitter stage 48 further comprises a third signal sub-path 58 and a fourth signal sub-path 60 that are connected to the third splitter unit 52. The signal sub-paths each comprise a filter circuit 62, an attenuator 64, and an amplifier 66.

It is noted that while the signal splitting circuit 20 is shown to have two splitter stages 28, 48 in FIG. 2, it is also conceivable that the signal splitter circuit 20 may comprise only a single splitter stage or more than two splitter stages.

In an embodiment, the signal splitting circuit 20 further comprises n signal outputs 68 that are configured to output n RF signals, wherein in general n is an integer greater than or equal to 2, for example greater than or equal to 4. In an embodiment, n is equal to the number of signal (sub-)paths of the last splitter stage of the signal splitting circuit 20.

In general, the signal outputs 68 are arranged at the end of the last splitter stage of the signal splitting circuit 20. In the specific example shown in FIG. 2, it holds n=j₂=4. Here, the signal outputs are arranged at the ends of the signal sub-paths 54, 56, 58, 60. Accordingly, the n RF output signals correspond to the n=j₂=4 RF signals processed by the signal sub-paths 54, 56, 58, 60.

In an embodiment, the switching matrix circuit 22 comprises n signal inputs 70, wherein each signal input 70 is connected to one of the RF signal outputs 68 of the signal splitting circuit 20. The switching matrix circuit 22 further comprises a plurality of signal outputs 72. In general, the switching matrix circuit 22 is configured to selectively forward m of the n RF signals received by the signal inputs 70 to the signal outputs 72, wherein m is an integer smaller than n.

In a certain embodiment shown in FIG. 2, the switching matrix circuit 22 comprises two switches 74 that are each connected to two of the signal inputs 70 and to one of the signal outputs 72. Accordingly, each switch 74 selects one of two RF signals received and forwards it to the respective signal output 72.

However, it is to be understood that the switching matrix circuit 22 may comprise an arbitrary number of switches arranged in an arbitrary topology, such that m of the n RF signals received by the signal inputs 70 are selectively forwarded to the signal outputs 72.

In general, the signal processing circuit 24 comprises at least two analog-to-digital converters (ADCs) 76 that are connected to the signal outputs 72. In an embodiment, the signal processing circuit 24 may comprise up to n-1 ADCs 76, for example m ADCs 76. In the embodiment shown in FIG. 2, the signal processing circuit 24 comprises two ADCs 76, wherein each ADC 76 is connected to one of the two signal outputs 72.

It is noted that arbitrary further signal shaping circuitry may be provided between the signal outputs 72 and the ADCs 76, such as amplifiers, attenuators, mixers, etc. Likewise, it is also conceivable that such signal shaping circuitry may be provided within the switching matrix circuit 22.

In an embodiment, the signal processing circuit 24 further comprises a digital signal processing (DSP) circuit 78 that is arranged downstream of the ADCs 76. The DSP circuit 78 may comprise a plurality of fast Fourier transform (FFT) circuits 80, wherein the plurality of FFT circuits 80 is connected to the at least two ADCs 76.

The functionality of the measurement circuit 18 will be described in more detail below.

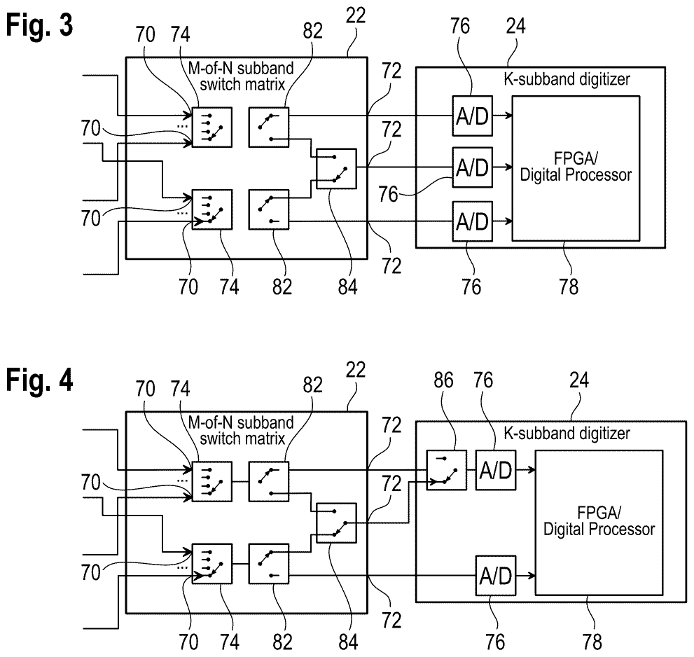

FIG. 3 shows another embodiment of the measurement circuit 18, wherein only the switching matrix circuit 22 and the signal processing circuit 24 are shown. Hereinafter, only the differences compared to the embodiment explained above with respect to FIG. 2 are described.

In this embodiment, the switching matrix circuit 22 comprises a first set of switches 74, for example m switches 74. The switching matrix circuit 22 further comprises a second set of switches 82 that are arranged downstream of the first set of switches 74, for example wherein the second set of switches 82 comprises m switches 82.

In an embodiment, the first set of switches 74 is configured to select m RF output signals of the n RF output signals received via the signal inputs 70. The m RF output signals are forwarded to the second of switches 82, namely one RF output signal to each switch 82.

In an embodiment, the switching matrix circuit 22 further comprises an additional selection switch 84 that is connected to each switch 82 of the second set of switches 82.

In the embodiment shown in FIG. 3, the signal processing circuit 24 comprises m+1 ADCs 76, wherein one of the ADCs 76 is connected to the additional selection switch 84. Accordingly, one of m RF output signals selected by the first set of switches 74 can, optionally, be forwarded to the ADC 76 being connected to the additional selection switch 84. This ADC 76 may have a higher bandwidth, higher sample rate and/or higher dynamic range than the remaining ADCs 76. Accordingly, one of the RF output signals can be digitized with increased accuracy, or an RF output signal having a higher bandwidth and/or dynamic range can be digitized.

FIG. 4 shows another embodiment of the measurement circuit 18, wherein only the switching matrix circuit 22 and the signal processing circuit 24 are shown. Hereinafter, only the differences compared to the embodiment explained above with respect to FIG. 3 are described.

In this embodiment, the signal processing circuit 24 comprises m ADCs 76. The signal processing circuit 24 comprises a further selection switch 86 that is connected to one of the switches 82 of the second set of switches 82 as well as to the additional selection switch 84. One of the ADCs 76 is connected to the further selection switch 86.

In this embodiment, it is theoretically sufficient to provide a single ADC 76, namely the ADC 76 being connected to the further selection switch 86, as each of the RF signals received by the switching matrix circuit 22 can be forwarded to that ADC 76.

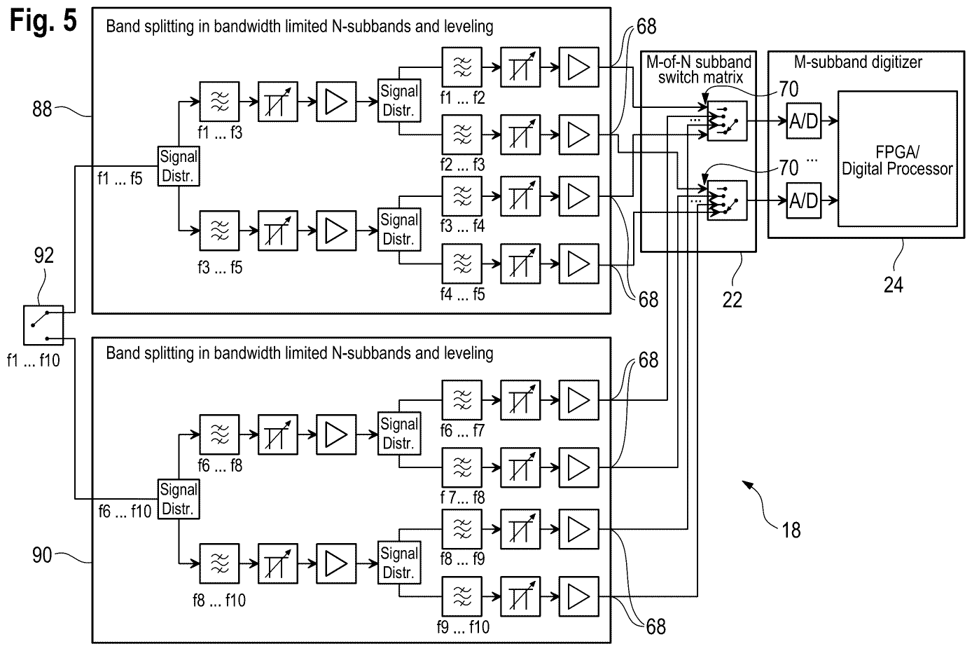

FIG. 5 shows another embodiment of the measurement circuit 18, wherein only the differences compared to the embodiment described above with reference to FIG. 2 are explained hereinafter.

In this embodiment, the measurement circuit 18 comprises a first signal splitting circuit 88, a second signal splitting circuit 90, and a switching circuit 92. The switching circuit 92 is connected to the at least one signal input 16, as well as to the first signal splitting circuit 88 and the second signal splitting circuit 90. The switching circuit 92 is configured to receive the RF input signal, and to selectively forward the RF input signal to either the first splitting circuit 88 or the second splitting circuit 90.

Therein, a useful signal of the RF input signal covers a frequency band spanning from a lower frequency f1 to an upper frequency f10>f5.

In an embodiment, the first signal splitting circuit 88 is configured like the signal splitting circuit 20 described above with reference to FIG. 2, i.e. the first signal splitting circuit is configured to process RF signals in the frequency range from f1 to f5. The second signal splitting circuit 90 is configured analogously to the first signal splitting circuit 88, but is configured to process a different frequency range, namely from f5 to f10. In an embodiment, the first signal splitting circuit 88 and the second signal splitting circuit 90 each have n signal outputs 68.

In this embodiment, the switching matrix circuit 22 has 2n signal inputs 70, which are connected to both the signal outputs 68 of the first signal splitting circuit 88 and the signal outputs 68 of the second signal splitting circuit 90.

Only one of the first signal splitting circuit 88 and the second signal splitting circuit 90 is active at a time due to the switching circuit 92 forwarding the RF input signal to only one of the first signal splitting circuit 88 and the second signal splitting circuit 90.

Thus, as described above with respect to the other embodiments, the switching matrix circuit 22 always receives n RF signals simultaneously, and selects m of these n RF signals as described above.

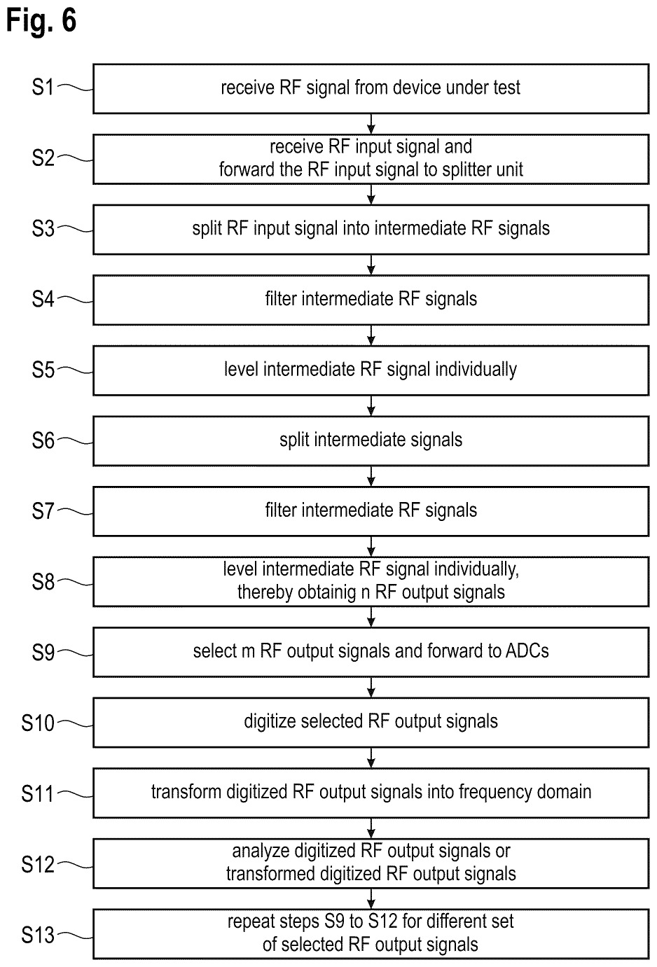

Irrespective of the embodiment, the test and/or measurement system 10 is configured to perform a signal processing method for analyzing at least a portion of a broadband signal, an example of which is described hereinafter with reference to FIG. 6.

In the following, the method is described with reference to the embodiment of FIG. 2, but it is to be understood that the steps described hereinafter likewise can be performed by the test and/or measurement system 10 according to any of the other embodiments.

An RF signal is received from the device under test 14 by the at least one signal input 16 and is forwarded to the measurement circuit 18 (step S1).

As already described above, the RF signal may be a broadband signal, for example a pulsed signal.

An RF input signal is received by the splitting circuit 20, or more precisely by the signal input 26, and is forwarded to the first splitter unit 30 (step S2).

The RF input signal may be the RF signal output by the device under test 14 or a processed version thereof.

The RF input signal is split into j₁ intermediate RF signals by the first splitter unit 30, and is forwarded to each of the signal processing paths 32, 34 (step S3).

In the embodiment shown in FIG. 2, j₁ is equal to 2.

In the signal processing paths 32, 34, the intermediate RF signals are filtered by the filter circuits 36, 42, thereby confining the intermediate RF signals to predefined frequency sub-bands (step S4).

For example, in the first signal processing path 32, the first filter circuit 36 confines the corresponding intermediate RF signal to the frequency band spanning f1 to f3.

In the second signal processing path 34, the second filter circuit 42 confines the corresponding intermediate RF signal to the frequency band spanning f3 to f5.

If necessary, the intermediate RF signals may be levelled independently in the signal processing paths 32, 34 (step S5).

In an embodiment, in the first signal processing path 32, the corresponding intermediate RF signal may be attenuated by the first attenuator 38 if the signal level of the frequency band from f1 to f3 is too high.

Alternatively, the corresponding intermediate RF signal may be amplified by the first amplifier 40 if the signal level of the frequency band from f1 to f3 is too low.

In the second signal processing path 34, the corresponding intermediate RF signal may be attenuated by the second attenuator 44 if the signal level of the frequency band from f3 to f5 is too high.

Alternatively, the corresponding intermediate RF signal may be amplified by the second amplifier 46 if the signal level of the frequency band from f3 to f5 is too low.

The resulting j₁ intermediate RF signals are forwarded to the second splitter unit 50 and to the third splitter unit 52.

The second splitter unit 50 and the third splitter unit 52 each split the corresponding received intermediate RF signal, thereby obtaining j₂ intermediate RF signals that are forwarded to the j₂ signal sub-paths 54, 56, 58, 60 (step S6).

The j₂ intermediate RF signals are filtered by the filter circuits 62 thereby confining the intermediate RF signals to predefined frequency sub-sets (step S7).

Therein, each of the j₂ intermediate RF signals is confined to a sub-set of frequencies that lies within the sub-band of frequencies of the RF intermediate signal it has originated from.

For example, in the first signal sub-path 54, the intermediate RF signal is confined to the frequency sub-set from f1 to f2, which lies within the original sub-band from f1 to f3. Therein, f2 is smaller than f3.

The different frequency sub-sets together cover the complete frequency range of the RF input signal, i.e. from f1 to f5.

If necessary, the j₂ intermediate RF signals may be levelled independently in the signal processing sub-paths 54, 56, 58, 60 (step S8).

In an embodiment, the j₂ intermediate RF signals may be attenuated and/or amplified by the attenuators 64 and/or the amplifiers 66, respectively.

The resulting j₂=n RF output signals are output via the signal outputs 68 and are forwarded to the switching matrix circuit 22.

The switching matrix circuit 22 selects m RF output signals of the n RF output signals, and forwards the selected RF output signals to the ADCs 76 (step S9).

Therein, the switching matrix circuit 22 may select RF output signals being adjacent in frequency domain, such that these neighboring RF output signals are forwarded to the ADCs 76.

It is noted that the individual steps described hereinafter are performed on the selected RF output signals simultaneously.

The selected RF output signals are digitized by the ADCs 76, thereby obtaining digitized RF signals (step S10).

Optionally, the ADCs 76 may digitally down-convert the frequencies of the selected RF output signals and/or decimate the selected RF output signals.

Alternative to the frequency down-conversion by the ADCs 76, corresponding analog mixer circuits may be provided upstream of the ADCs 76, or corresponding digital mixer circuits may be provided downstream of the ADCs 76.

In an embodiment, the selected RF output signals may be down-converted into the baseband.

The digitized RF signals are forwarded to the DSP circuit 78.

Optionally, the digitized RF signals are transformed into frequency domain by the FFT circuits 80, namely by an FFT (step S11).

Therein, frequency bins of the FFT circuits 80 are distributed over the respective sub-bands associated with the signals digitized by the ADCs 76. For example, each FFT circuit 80 may have at least 1024, 2048, or 4096 frequency bins. As another example, a width of the individual frequency bins may be smaller than 200 kHz, 150 kHz, 100 kHz, or 60 kHz. However, it is to be understood that any other suitable number of frequency bins, and any other suitable width of the frequency bins may be used.

The digitized RF signals or the digitized RF signals transformed into frequency domain are analyzed by the DSP circuit 78, thereby obtaining at least one performance parameter associated with the device under test 14 (step S12).

In general, the at least one performance parameter is indicative of a performance of the device under test 14, i.e. the at least one performance parameter indicates whether the device under test 14 is functioning correctly.

For example, the at least one performance parameter may comprise an error vector magnitude, a noise level, jitter, a signal-to-noise ratio, and/or any other suitable type of parameter.

Steps S9 to S12 described above may be repeated for a different set of m RF output signals selected by the switching matrix circuit 22 (step S13).

In an embodiment, steps S9 to S12 may be repeated until all n RF output signals of the signal splitting circuit 20 are analyzed.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc. In an embodiment, these components, or parts thereof, may be grouped in a single location or distributed over a wide area. In circumstances where the components are distributed, the components are accessible to each other via communication links.

In an embodiment, one or more of the components of the test and/or measurement system 10 referenced above include circuitry programmed to carry out one or more steps of any of the methods disclosed herein. In an embodiment, one or more computer-readable media associated with or accessible by such circuitry contains computer readable instructions embodied thereon that, when executed by such circuitry, cause the component or circuity to perform one or more steps of any of the methods disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible by a computing device, such as processor circuitry, etc., or other circuity disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

It will be appreciated that in one or more embodiments, the term computer or computing device can include, for example, any computing device or processing structure, including but not limited to a processor (e.g., a microprocessor), a central processing unit (CPU), a digital signal processor (DSP), an application-specific integrated circuit (ASIC), a field-programmable gate array (FPGA), a system on a chip (SoC), a graphics processing unit (GPU) or the like, or any combinations thereof.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the detailed description herein, references to “one embodiment”, “an embodiment”, “an example embodiment”, “one or more embodiments”, “some embodiments”, etc., indicate that the embodiment or embodiments described may include a particular feature, structure, or characteristic, but every embodiment may not necessarily include the particular feature, structure, or characteristic. Moreover, such phrases are not necessarily referring to the same embodiment or embodiments. In addition, when a particular feature, structure, or characteristic is described in connection with an embodiment or embodiments, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. While the stated range includes one or both of the limits, ranges excluding either or both of those included limits are also included in the disclosure

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A test and/or measurement system for analyzing at least a portion of a broadband signal, the test and/or measurement system comprising at least one signal splitting circuit, a switching matrix circuit, and a signal processing circuit,
wherein the at least one signal splitting circuit comprises a signal input being configured to receive a radio frequency, RF, input signal,
wherein the at least one signal splitting circuit comprises n signal outputs, wherein n is an integer greater than or equal to 2,
wherein the at least one signal splitting circuit is configured to split the RF input signal into n RF output signals, wherein the n RF output signals correspond to different sub-bands of the RF input signal, and wherein the at least one signal splitting circuit is configured to forward the n RF output signals to the n signal outputs,
wherein the switching matrix circuit is connected to each of the n signal outputs,
wherein the switching matrix circuit is configured to selectively output m RF output signals of the n RF output signals, wherein m is an integer smaller than n,
and wherein the signal processing circuit is configured to process the m RF output signals in parallel.

2. The test and/or measurement system of claim 1, wherein the at least one signal splitting circuit comprises at least one filter circuit for each of the n RF output signals, wherein the filter circuits are configured to confine the n RF output signals to the respective sub-band.

3. The test and/or measurement system of claim 1, wherein the signal processing circuit comprises at least two analog-to-digital converters, ADCs, wherein the at least two ADCs are arranged in parallel.

4. The test and/or measurement system of claim 3, wherein the at least two different ADCs are configured to digitize different sub-bands of the RF input signal simultaneously.

5. The test and/or measurement system of claim 3, wherein the at least two ADCs are each configured to digitally down-convert a frequency of the respective RF output signal and/or to decimate the respective RF output signal.

6. The test and/or measurement system of claim 3, wherein the at least one signal splitting circuit, the switching matrix circuit, and the signal processing circuit are free of frequency conversion mixers upstream of the at least two ADCs.

7. The test and/or measurement system of claim 3, wherein the signal processing circuit comprises a digital signal processing circuit being arranged downstream of the at least two of ADCs, wherein the digital signal processing circuit is configured to analyze signals digitized by the at least two ADCs in parallel.

8. The test and/or measurement system of claim 7, wherein the digital signal processing circuit comprises a plurality of fast Fourier transform, FFT, circuits, wherein the plurality of FFT circuits is connected to the at least two ADCs, wherein the plurality of FFT circuits is configured to apply an FFT to one of the signals digitized by the at least two ADCs, respectively, and wherein frequency bins of the FFT circuits are distributed over the respective sub-bands associated with the signals digitized by the at least two ADCs.

9. The test and/or measurement system of claim 1, wherein the at least one signal splitting circuit is configured to level the n RF output signals individually.

10. The test and/or measurement system of claim 9, wherein the at least one signal splitting circuit comprises at least one amplifier for each of the n RF output signals.

11. The test and/or measurement system of claim 9, wherein the at least one signal splitting circuit comprises at least one attenuator for each of the n RF output signals.

12. The test and/or measurement system of claim 1, wherein the at least one splitting circuit comprises a first splitter stage, wherein the first splitter stage is configured to split the RF input signal into a first set of intermediate RF signals, wherein the first set of intermediate RF signals correspond to different sub-bands of the RF input signal.

13. The test and/or measurement system of claim 12, wherein the first splitter stage comprises at least one of an amplifier, an attenuator, or a filter circuit for each of the intermediate RF signals.

14. The test and/or measurement system of claim 12, wherein the at least one splitting circuit comprises a second splitter stage that is arranged downstream of the first splitter stage, wherein the second splitter stage is configured to split the first set of intermediate RF signals into a second set of intermediate RF signals.

15. The test and/or measurement system of claim 14, wherein the second splitter stage comprises at least one of an amplifier, an attenuator, or a filter circuit for each of the intermediate RF signals.

16. The test and/or measurement system of claim 1, further comprising a switching circuit, wherein the at least one splitting circuit comprises a first splitting circuit and a second splitting circuit, wherein the first splitting circuit and the second splitting circuit are each connected to the switching circuit, wherein the switching circuit is configured to receive the RF input signal, and wherein the switching circuit is configured to selectively forward the RF input signal to either the first splitting circuit or the second splitting circuit.

17. The test and/or measurement system of claim 16, wherein the switching matrix circuit is connected to both the first splitting circuit and the second splitting circuit.

18. The test and/or measurement system of claim 16, wherein the first splitting circuit and the second splitting circuit are configured to process different frequency portions of the RF input signal.

19. The test and/or measurement system of claim 1, wherein the different sub-bands are overlap-free.

20. A signal processing method for analyzing at least a portion of a broadband signal, the signal processing method comprising:
receiving, by at least one signal splitting circuit, a radio frequency, RF, input signal;
splitting, by the at least one splitting circuit, the RF input signal into n RF output signals, wherein the n RF output signals correspond to different sub-bands of the RF input signal, and wherein n is an integer greater than or equal to 2;
outputting, by the splitting circuit, the n RF output signals via n signal outputs;
selectively outputting, by a switching matrix circuit, m RF output signals of the n RF output signals, wherein m is an integer smaller than n; and
processing, by a signal processing circuit, the m RF output signals in parallel.
